(19) United States
(12) Patent Application Publication
(10) Pub. No.: US 2008/0098276 A1
(43) Pub. Date: Apr. 24, 2008

(54) SEMICONDUCTOR INTEGRATED CIRCUIT

(75) Inventor: Toshimichi Naoi, Tokyo (JP)

Correspondence Address: VOLENTINE & WHITT PLLC, ONE FREEDOM SQUARE, 11951 FREEDOM DRIVE SUITE 1260, RESTON, VA, 20190, US

(73) Assignee: OKI ELECTRIC INDUSTRY CO., LTD., Tokyo (JP)

(21) Appl. No.: 11/848,307

(22) Filed: Aug. 31, 2007

(30) Foreign Application Priority Data
Oct. 19, 2006 (JP) 2006-284856

(51) Int. Cl. H03M 13/00

(52) U.S. Cl. 714/751

(57) ABSTRACT

The present invention provides a data transmission method capable of suppressing degradation in data rate while improving a bit error rate of transmission data, and transmitters and receivers employed in the data transmission method. On the transmitting side, a CRC bit is added to an input information bit sequence in block units. The information bit sequence subsequent to the addition of the CRC bit is modulated and transmitted to the receiving side. On the receiving side, the information bit sequence is received and demodulated. A CRC check for the post-demodulation information bit sequence is performed. When the above result of CRC check is found to be negative-acknowledged, a NACK signal is transmitted to the transmitting side. On the transmitting side, when the NACK signal transmitted from the receiving side is received after modulation/transmission of the information bit sequence, the information bit sequence subsequent to the addition of the CRC bit is systematically encoded to generate a first parity bit sequence. The first parity bit sequence is modulated and transmitted to the receiving side. On the receiving side, the first parity bit sequence is received and demodulated. The post-demodulation information bit sequence is subjected to error correction decoding using the demodulated first parity bit sequence.

### BACKGROUND OF THE INVENTION

The present invention relates to a data transmission method for transmitting an information bit sequence in a digital communication system, and to transmitters and receivers for implementing the data transmission method.

In data transmission employed in a digital communication system, communication quality is represented by a bit error rate (hereinafter abbreviated as “BER”). As means (so-called error control techniques) for enhancing BER, a forward error correction (hereinafter abbreviated as “FEC”) and an automatic repeat request (hereinafter abbreviated as “ARQ”) are useful. They have actually been put into practical use in many systems.

In a cellular phone system using, for example, a WCDMA (Wideband Code Division Multiple Access) type communication standard, FEC has been adopted as an essential element technique. ARQ has been adopted in a wireless LAN system like IEEE802.11b. Further, FEC and ARQ have been utilized in combination with each other in high-speed wireless communications called broadband, for example, IEEE802.11a/g.

Both error control techniques need to divide a bit sequence into finite lengths (bit sequences of finite length will hereinafter be represented as blocks) and adapt the error correction technique every block. ARQ can be implemented in interactive communications but cannot be used in broadcast communications such as broadcast. Thus, a digital communication having utilized FEC and ARQ in combination with each other is an interactive blocked communication, e.g., a packet communication.

Upon an FEC-based control operation, a parity bit sequence by which an error bit sequence can be estimated, is added to an information bit sequence and the result of addition thereof is transmitted (refer to, for example, a patent document 1 (Japanese Unexamined Patent Publication No. 2002-204278)). On the receiving side, the error position of a reception bit sequence is estimated from the parity bit sequence and thereby a bit error is corrected. Since the reception bit sequence is constituted of the information bit sequence and parity bit sequence, the data rate of each information bit is lowered than that of each reception bit (transmission bit on the transmitting side). The higher the encoding rate corresponding to the ratio of the information bits in the reception bits, the fewer the reduction in data rate.

Upon an ARQ-based control operation, an error detection code (even parity bit or CRC: Cyclic Redundant Code) is added to an information bit sequence and transmitted. On the receiving side, the presence of an error is detected according to the error detection code. When the error is found not to be exist, ACK (Acknowledgment) is answered. When the error is found to exist, NACK (Negative ACK) is answered. Incidentally, an error correction cannot be performed because an error position is not known or recognized. There is also known a system in which no NACK is answered.

A data rate of each information bit based on ARQ is degraded in a manner similar to FEC due to the property that the error detection code is added and the following data transmission cannot be performed until ACK or NACK is received on the transmitting side.

Both systems of FEC and ARQ improve BER by degrading the data rate. In IEEE802.11g (wireless LAN) defined as the system in which FEC and ARQ are utilized in combination, FEC is mounted in a physical layer, and its configuration is of a configuration of a modem of PBCC shown in FIGS. 8 to 10 of Page 166 in a non-patent document 1 (“802.11 High-Speed Wireless LAN Text” by Hideaki Matsue and Masahiro Morikura).

ARQ is mounted in a MAC sublayer and transmission using ACK is shown in FIGS. 4 and 5 of Page 70 in the non-patent document 1 as its configuration.

As described above, both FEC and ARQ improve the bit error rate BER in place of the degradation in data rate. Although the degradation in data rate is constant, the improvement in BER depends upon the state of a transmission line through which data is transmitted. When the state of the transmission line is good, that is, when data transmission can normally be made even in a state in which no FEC is done, the effect of enhancing BER by FEC does not appear, thus resulting in needless degradation in data rate. The control that FEC is not performed where the state of the transmission line is good, needs to estimate the state of the transmission line with a high degree of accuracy before the data transmission. It is difficult to realize such estimation.

### SUMMARY OF THE INVENTION

Thus, an object of the present invention is to provide a data transmission method capable of suppressing degradation in data rate while improving a bit error rate of transmission data, and transmitters and receivers for implementing the data transmission method.

According to one aspect of the present invention, for attaining the above object, there is provided a data transmission method comprising the following steps: on a transmitting side,

a first transmission step for adding a CRC (cyclic redundancy check) bit to an input information bit sequence in block units, modulating the information bit sequence subsequent to the addition of the CRC bit and transmitting the same to a receiving side; and

a second transmission step for, when a first NACK (negative-acknowledgement response) signal transmitted from the receiving side is received after execution of the first transmission step, systematically encoding the information bit sequence subsequent to the addition of the CRC bit thereby to generate a fist parity bit sequence, modulating the first parity bit sequence and transmitting the same to the receiving side; and comprising the following steps: on the receiving side,

a first check step for receiving the information bit sequence, demodulating the same and performing a CRC check for the post-demodulation information bit sequence;

a first NACK transmission step for transmitting the first NACK signal to the transmitting side when a result of the CRC check is found to be negative-acknowledged; and

a correction decoding step for receiving the first parity bit sequence, demodulating the same and performing error correction decoding on the post-demodulation information bit sequence using the demodulated first parity bit sequence.

According to another aspect of the present invention, for attaining the above object, there is provided a transmitter comprising:

CRC adding means which adds a CRC bit to an input information bit sequence in block units;

encoding means which systematically encodes the information bit sequence subsequent to the addition of the CRC bit by the CRC adding means thereby to generate a first parity bit sequence;

selecting means which selectively outputs either one of the information bit sequence subsequent to the addition of the CRC bit and the first parity bit sequence; and

modulating means which modulates the first bit sequence outputted by the selecting means and transmits the same therefrom.

According to a further aspect of the present invention, for attaining the above object, there is provided a receiver comprising:

demodulating means which individually receives, in block units, an information bit sequence subsequent to addition of a CRC bit and a first parity bit sequence obtained by systematically encoding the information bit sequence subsequent to the addition of the CRC bit;

decoding means which performs error correction decoding on the information bit sequence demodulated by the demodulating means, using the first parity bit sequence demodulated by the demodulating means; and

check means which performs a CRC check for the information bit sequence demodulated by the demodulating means or the information bit sequence subjected to the error correction decoding by the decoding means.

According to the data transmission method of the present invention, when only an information bit sequence subsequent to addition of each CRC bit is modulated and transmitted, and the information bit sequence cannot be received normally because the state of a transmission line for the information bit sequence is bad, only a first parity bit sequence is modulated and transmitted. It is, therefore, possible to suppress degradation in data rate while improving the bit error rate of transmission data. It is also unnecessary to estimate the state of the transmission line with a high degree of accuracy before the transmission of the bit sequence.

According to the transmitter of the present invention, when only an information bit sequence subsequent to addition of each CRC bit thereto is modulated and transmitted, and the information bit sequence cannot be received normally, only a first parity bit sequence can be modulated and transmitted.

According to the receiver of the present invention, when only an information bit sequence subsequent to addition of each CRC bit thereto is received, it is demodulated and subjected to a CRC check. When only a first parity bit sequence is received, it is demodulated and the information bit sequence is subjected to error correction decoding using the post-demodulation first parity bit sequence, whereby the CRC check can be made on the information bit sequence subsequent to the error correction decoding.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1 is a block diagram showing a configuration of a digital communication system to which a data transmission method of the present invention is applied;

FIG. 2 is a block diagram illustrating a configuration of a transmitter of a transmission-side communication device in the system of FIG. 1;

FIG. 3 is a block diagram depicting a configuration of a turbo encoder in the transmitter of FIG. 2;

FIG. 4 is a block diagram showing a configuration of a receiver of a reception-side communication device in the system of FIG. 1;

FIG. 5 is a block diagram illustrating a configuration of a turbo encoder in the receiver of FIG. 4;

FIG. 6 is a sequence diagram showing data transmission of the system of FIG. 1;

FIG. 7 is a block diagram illustrating another configuration of the transmitter of the transmission-side communication device in the system of FIG. 1;

FIG. 8 is a block diagram illustrating another configuration of the receiver of the reception-side communication device in the system of FIG. 1; and

FIG. 9 is a sequence diagram showing data transmission of a system equipped with the transmitter of FIG. 7 and the receiver of FIG. 8.

### DETAILED DESCRIPTION OF THE PREFERRED EMBODIMENTS

Preferred embodiments of the present invention will hereinafter be described with reference to the accompanying drawings.

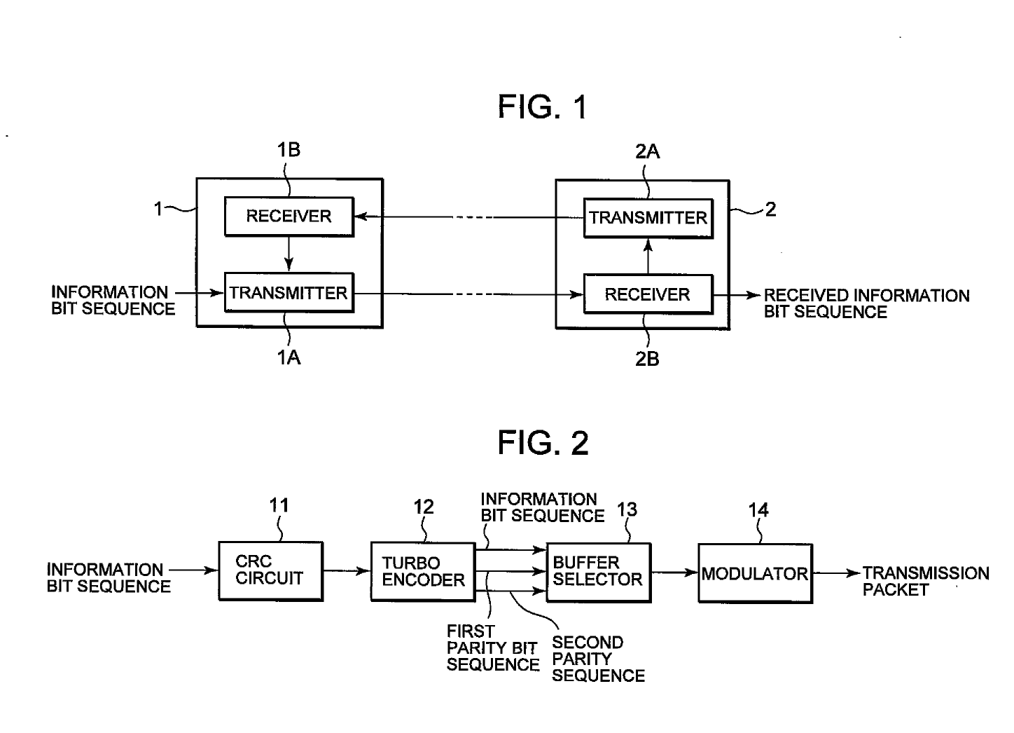

FIG. 1 shows a configuration of a digital communication system that has adopted a data transmission method according to the present invention. The digital communication system is equipped with a data transmission-side communication device 1 and a data reception-side communication device 2. Further, the data transmission-side communication device 1 and the data reception-side communication device 2 are both equipped with transmitters 1A and 2A and receivers 1B and 2B.

The transmitter 1A of the data transmission-side communication device 1 is equipped with a CRC circuit 11, a turbo encoder 12, a buffer selector 13 and a modulator 14 as shown in FIG. 2. The CRC circuit 11 adds a CRC bit to an input bit sequence every transmission packet unit and outputs it to the turbo encoder 12.

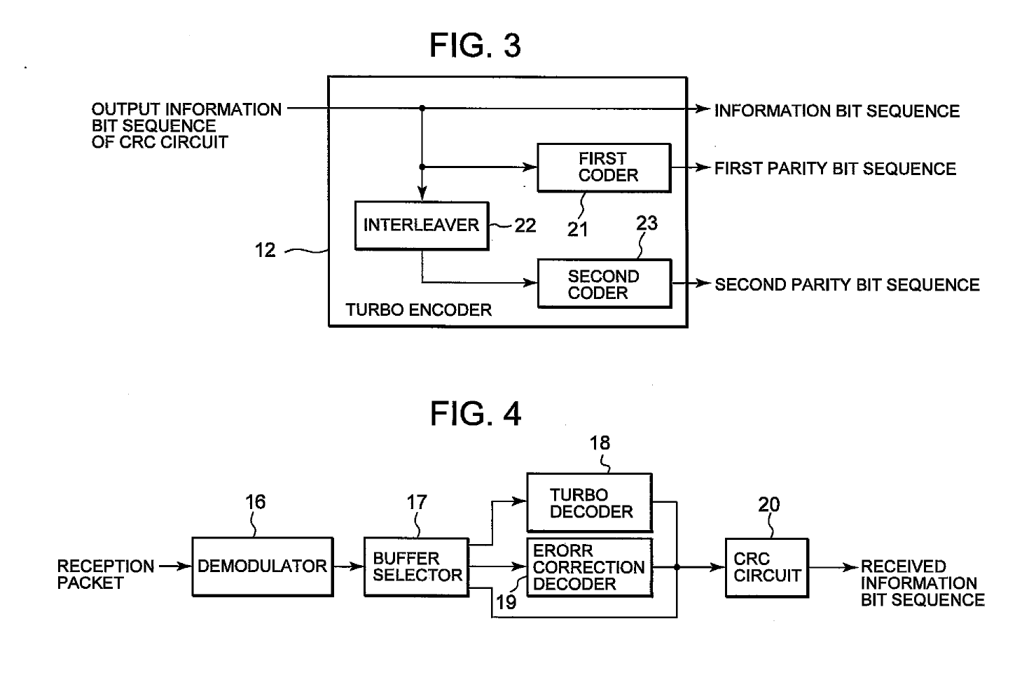

As shown in FIG. 3, the turbo encoder 12 has a first coder 21, an interleaver 22 and a second coder 23. The inputs of the first coder 21 and the interleaver 22 are connected to the output of the CRC circuit 11. The first coder 21 encodes a data sequence added with the CRC bit supplied from the CRC circuit 11 to create a first parity bit sequence. The interleaver 22 rearranges a sequence or order of bits of the data sequence added with the CRC bit and outputs the rearranged data sequence to the second coder 23. The second coder 23 encodes the data sequence supplied from the interleaver 22 to create a second parity bit sequence. The turbo encoder 12 outputs the information bit sequence added with the CRC bit, the first parity bit sequence and the second parity bit sequence to the buffer selector 13 individually.

The buffer selector 13 allows a buffer (not shown) to hold or retain the information bit sequence, the first parity bit sequence and the second parity bit sequence supplied from the turbo encoder 12 and selectively outputs any one of these bit sequences to the modulator 14. The modulator 14 modulates one bit sequence supplied from the buffer selector 13 and transmits the modulated bit sequence as a packet. That is, the modulator 14 performs any one of (1) modulation/transmission of only the information bit sequence, (2) modulation/transmission of only the first parity bit sequence, and (3) modulation/transmission of only the second parity bit sequence. Incidentally, whether any of (1) to (3) has been executed is described in the header of the transmission packet on the transmitting side. It is discriminated on the receiving side from the contents of the packet's header which bit sequence alone has been transmitted.

As shown in FIG. 4, the receiver 2B of the data reception-side communication device 2 is equipped with a demodulator 16, a buffer selector 17, a turbo encoder 18, an error correction decoder 19 and a CRC circuit 20. The demodulator 16 receives a packet transmitted from the transmitter 1A and demodulates a data portion of its received packet to obtain bit sequences. The buffer selector 17 is connected to the output of the demodulator 16.

The buffer selector 17 allows a buffer (not shown) to store the bit sequences obtained by demodulation of the demodulator 16 and selectively relay-supplies the stored bit sequences to the turbo encoder 18, the error correction decoder 19 and the CRC circuit 20.

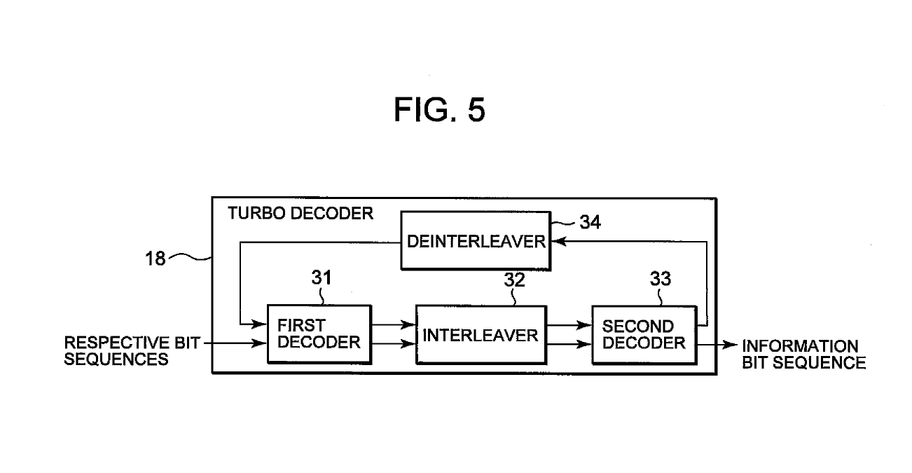

The turbo encoder 18 is provided to turbo-decode the bit sequences (information bit sequence, first parity bit sequence and second parity bit sequence) obtained by demodulation. As shown in FIG. 5, the turbo encoder 18 includes a first decoder 31, an interleaver 32, a second decoder 33 and a deinterleaver 34. The buffer selector 17 supplies each received bit sequence to the first decoder 31, and the deinterleaver 34 supplies reliability information to the first decoder 31. The first decoder 31 effects a decoding process on the received bit sequence, using the reliability information and generates an output indicative of an increase in reliability information. The interleaver 32 rearranges the received bit sequence and the increase in the reliability information subsequent to the decoding process. The second decoder 33 performs a decoding process using the received bit sequences and the increase in the reliability information subsequent to the decoding process both rearranged by the interleaver 32, calculates the reliability information and supplies the result of calculation to the deinterleaver 34. The deinterleaver 34 gives back or returns the rearrangement thereof by the interleaver 32. The result of its return becomes reliability information to be supplied to the first decoder 31. Executing the above operation a few times to a few dozen times repeatedly at the turbo decoder 18 yields a result of decoding from the second decoder 33.

The error correction decoder 19 effects error correction decoding on the bit sequences (information bit sequence and first parity bit sequence) obtained by demodulation. That is, the error correction decoder 19 estimates an error position of the information bit sequence from the first parity bit sequence and corrects a bit error. The information bit sequence subsequent to the bit error correction is supplied to the CRC circuit 20.

The outputs of the demodulator 16, turbo decoder 18 and error correction decoder 19 are respectively connected to the CRC circuit 20. The CRC circuit 20 performs a CRC check for the information bit sequence supplied in packet units from either one of the turbo decoder 17 and the error correction decoder 19 according to the CRC bit added to within each packet. The result of such a CRC check is supplied to the transmitter 2A of the reception-side communication device 2.

When the above result of CRC check is found to be affirmative or acknowledged, the transmitter 2A sends a response packet indicative of ACK. When the result of CRC check is found to be negative or negative-acknowledged, the transmitter 2A sends a response packet indicative of NACK.

The receiver 1B of the data transmission-side communication device 1 receives the response packet transmitted from the transmitter 2A and discriminates or determines the contents of the received response packet, and supplies the result of its discrimination to the transmitter 1A.

Incidentally, the transmitter 2A of the reception-side communication device 2 and the receiver 1B of the data transmission-side communication device 1 can make use of such a configuration as employed in a system like, specifically, a W (wireless) LAN.

It is possible to communicate between the data transmission-side communication device 1 and the data reception-side communication device 2 through wire signals or wireless signals.

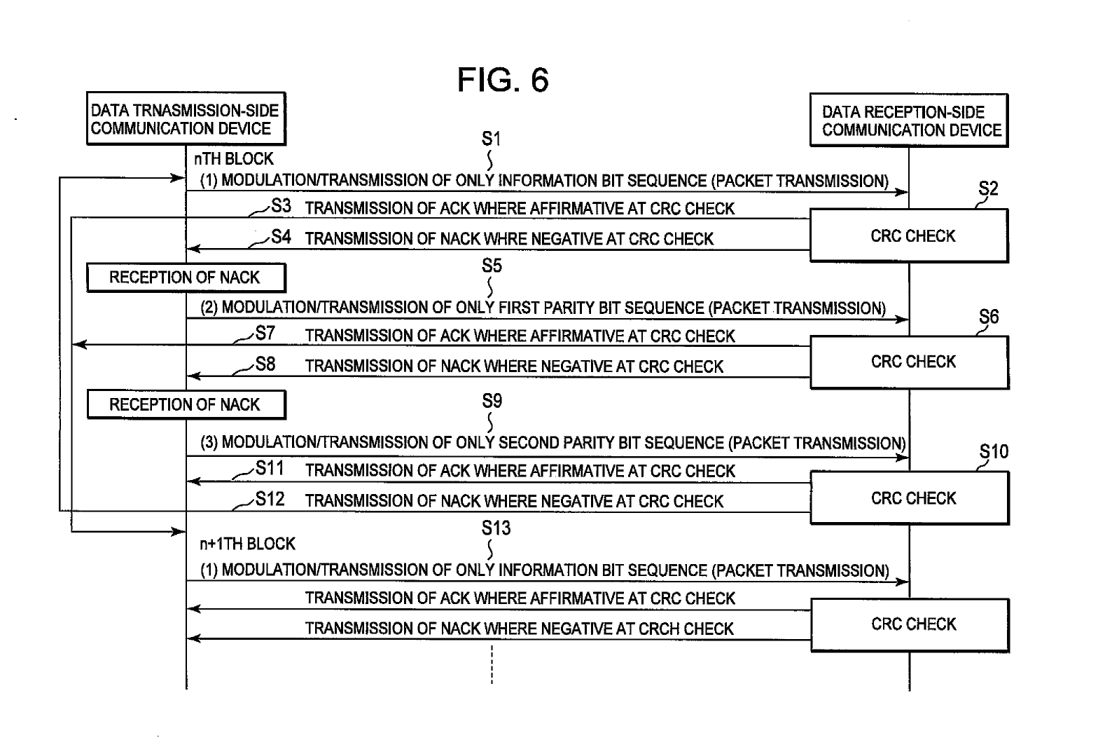

The operation of the digital communication system of such a configuration at the time that an information bit sequence corresponding to data is transmitted from the data transmission-side communication device 1 to the data reception-side communication device 2, will next be explained with reference to a sequence diagram shown in FIG. 6.

In the data transmission-side communication device 1, the transmitter 1A first executes the modulation/transmission of only the information bit sequence described in the above (1) (Step S1). That is, in the transmitter 1A, the buffer selector 13 selects an information bit sequence corresponding to an nth block outputted this time from the turbo encoder 12 and relay-supplies it to the modulator 14. An initial value of n is 1. Thus, a transmission packet corresponding to only the information bit sequence is transmitted from the modulator 14 to the receiver 2B of the data reception-side communication device 2.

In the receiver 2B of the data reception-side communication device 2, the packet is received from the communication device 1 and the information bit sequence lying in the packet is demodulated by the demodulator 16. The demodulated information bit sequence is stored in the corresponding buffer in the buffer selector 17 from which it is supplied to the CRC circuit 20.

The CRC circuit 20 performs a CRC check for the demodulated information bit sequence (Step S2). The result of its CRC check is supplied to the transmitter 2A of the reception-side communication device 2.

When the above result of CRC check is found to be affirmative or acknowledged, the information bit sequence corresponding to the nth block is obtained as normal bit data. Therefore, the transmitter 2A sends a response packet (affirmative or acknowledgement response signal) indicative of ACK to the data transmission-side communication device 1 (Step S3). When the result of CRC result is found to be negative or negative-acknowledged, the information bit sequence corresponding to the nth block cannot be obtained as the normal bit data. Therefore, the transmitter 2A sends a response packet (negative or negative-acknowledgement response signal) indicative of NACK to the communication device 1 (Step S4).

When the response packet indicative of NACK is received by the receiver 1B of the data transmission-side communication device 1, the transmitter 1A executes the modulation/transmission of only the first parity bit sequence described in the above (2) (Step S5). That is, in the transmitter 1A, the buffer selector 13 selects a first parity bit sequence outputted this time from the turbo encoder 12 and relay-supplies it to the modulator 14. Thus, a transmission packet corresponding to only the first parity bit sequence is transmitted from the modulator 14 to the receiver 2B of the data reception-side communication device 2.

In the receiver 2B of the data reception-side communication device 2, the packet corresponding to only the first parity bit sequence is received from the communication device 1 as a bit sequence. The first parity bit sequence in the packet is demodulated by the demodulator 16. The demodulated first parity bit sequence is stored in the corresponding buffer provided within the buffer selector 17 from which it is supplied to the error correction decoder 19. The information bit sequence already stored in the buffer lying in the buffer selector 17 is also supplied from the buffer selector 17 to the error correction decoder 19. The error correction decoder 19 performs error correction decoding on the information bit sequence using the first parity bit sequence. The information bit sequence subsequent to the bit error correction is supplied to the CRC circuit 20.

The CRC circuit 20 performs a CRC check for the demodulated information bit sequence (Step S6). The result of its CRC check is supplied to the transmitter 2A of the reception-side communication device 2.

When the above result of CRC check is found to be affirmative or acknowledged, the transmitter 2A sends a response packet indicative of ACK to the data transmission-side communication device 1 (Step S7). When the result of CRC check is found to be negative or negative-acknowledged, the transmitter 2A transmits a response packet indicative of NACK to the communication device 1 (Step S8).

When the response packet indicative of NACK is received by the receiver 1B of the data transmission-side communication device 1, the transmitter 1A executes the modulation/transmission of only the second parity bit sequence described in the above (3) (Step S9). That is, in the transmitter 1A, the buffer selector 13 selects a second parity bit sequence outputted this time from the turbo encoder 12 and relay-supplies it to the modulator 14. Thus, a transmission packet corresponding to only the second parity bit sequence is transmitted from the modulator 14 to the receiver 2B of the data reception-side communication device 2.

In the receiver 2B of the data reception-side communication device 2, the packet corresponding to only the second parity bit sequence is received from the communication device 1 as a bit sequence. The second parity bit sequence in the packet is demodulated by the demodulator 16. The demodulated second parity bit sequence is stored in the corresponding buffer provided within the buffer selector 17 from which it is supplied to the error correction decoder 19. The information bit sequence and first parity bit sequence already stored in the buffer of the buffer selector 17 are also supplied from the buffer selector 17 to the error correction decoder 19. The error correction decoder 19 performs error correction decoding on the information bit sequence using the first parity bit sequence and the second parity bit sequence. The information bit sequence subsequent to the bit error correction is supplied to the CRC circuit 20.

The CRC circuit 20 performs a CRC check for the demodulated information bit sequence (Step S10). The result of its CRC check is supplied to the transmitter 2A of the reception-side communication device 2.

When the above result of CRC check is found to be affirmative or acknowledged, the transmitter 2A sends a response packet indicative of ACK to the data transmission-side communication device 1 (Step S11). When the result of CRC check is found to be negative or negative-acknowledged, the transmitter 2A sends a response packet indicative of NACK to the communication device 1 (Step S12).

When the response packet indicative of NACK is received by the receiver 1B of the data transmission-side communication device 1, the routine operation of the sequence diagram is returned to Step S1, where the transmitter 1A executes the modulation/transmission of only the information bit sequence corresponding to the nth block again.

When the response packet indicative of ACK is received by the receiver 1B of the data transmission-side communication device 1, the transmitter 1A selects an information bit sequence corresponding to an n+1th block outputted next from the turbo encoder 12 and relay-supplies it to the modulator 14. Thus, a transmission packet related to only the information bit sequence corresponding to the n+1th block is transmitted from the modulator 14 to the receiver 2B of the data reception-side communication device 2 (Step S13).

Thus, in the digital communication system according to the present embodiment, data communications can be done at a high data rate where only the information bit sequence of the information bit sequence and the first and second parity bit sequences is first transmitted and the reception-side communication device 2 can normally receive the information bit sequence because the state of a transmission line is satisfactory. When the information bit sequence cannot be received normally because the state of the transmission line is in a bad condition, only the first parity bit sequence is transmitted and the reception-side communication device effects error correction decoding on the previously-received information bit sequence using the first parity bit sequence. Since the parity bit sequence is, although depending upon an encoding rate, reduced in the number of bits as compared with the information bit sequence where the encoding rate exceeds ½, data communications can be carried out at a high bit rate as compared with the case in which only ARQ that the information bit sequence is transmitted twice, is adopted where it cannot be received normally. When although the error correction decoding is performed using the first parity bit sequence because the transmission line is worse, bit data about the information bit sequence cannot be obtained normally, only the second parity bit sequence is transmitted and hence the reception-side communication device effects error correction decoding on the information bit sequence using the first parity bit sequence and the second parity bit sequence. That is, turbo decoding corresponding to powerful error correction decoding is executed. Thus, according to the digital communication system of the present embodiment, the information bit sequence can be transmitted at a bit rate corresponding to the transmission state of the transmission line without estimating the transmission state thereof.

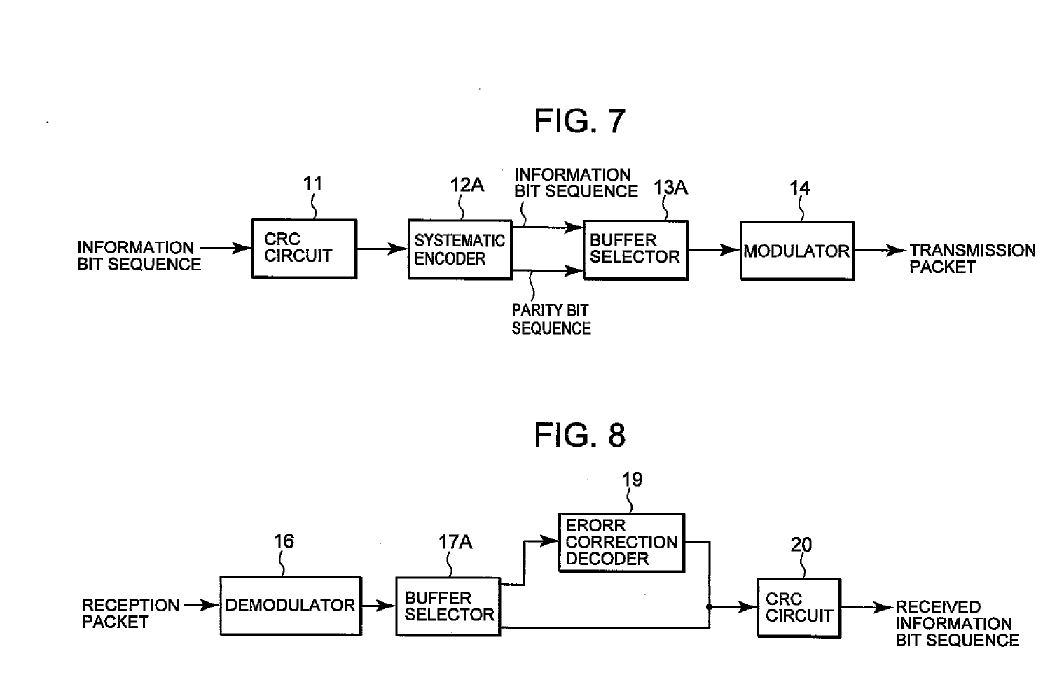

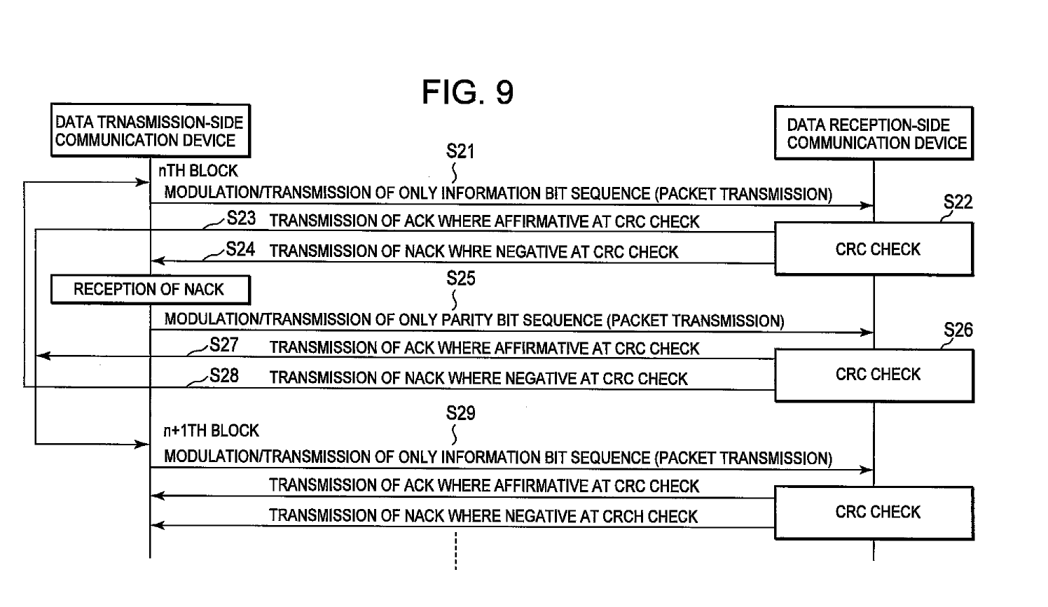

FIG. 7 shows another configuration example of the transmitter 1A of the data transmission-side communication device 1 as another embodiment of the present invention. The transmitter 1A of FIG. 7 includes a CRC circuit 11, a systematic encoder 12A, a buffer selector 13A and a modulator 14. The systematic encoder 12A encodes a data sequence added with a CRC bit supplied from the CRC circuit 11 to create a parity bit sequence and outputs it therefrom. Further, the systematic encoder 12A multiplexes the data sequence added with the CRC bit and the parity bit sequence and outputs the result of multiplexing as an information bit sequence. The buffer selector 13A allows a buffer (not shown) to retain or hold the information bit sequence and parity bit sequence supplied from the systematic encoder 12A and selectively outputs either one of these bit sequences to the modulator 14. The transmitter 1A is identical in other configuration to that shown in FIG. 2 except that the turbo encoder 12 is not provided.

FIG. 8 shows another configuration example of the receiver 2B of the data reception-side communication device 2, corresponding to the transmitter 1A of FIG. 7 as another embodiment of the present invention. The receiver 2B of FIG. 8 is equipped with a demodulator 16, a buffer selector 17A, an error correction decoder 19 and a CRC circuit 20. The buffer selector 17A allows a buffer (not shown) to store each bit sequence obtained by demodulation of the demodulator 16 and selectively relay-supplies the stored bit sequence to the error correction decoder 19 and the CRC circuit 20. The receiver 2B is identical in other configuration to that shown in FIG. 4 except that the turbo decoder 18 is not provided.

The operation of a digital communication system configured so as to have the transmitter 1A of FIG. 7 and the receiver 2B of FIG. 8 where an information bit sequence corresponding to data is transmitted from the data transmission-side communication device 1 to the data reception-side communication device 2, will next be explained.

In the data transmission-side communication device 1, the transmitter 1A first executes modulation/transmission of only the information bit sequence (Step S21). That is, in the transmitter 1A, the buffer selector 13A selects an information bit sequence corresponding to an nth block outputted this time from the systematic encoder 12A and relay-supplies it to the modulator 14. An initial value of n is 1. Thus, a transmission packet corresponding to only the information bit sequence is transmitted from the modulator 14 to the receiver 2B of the data reception-side communication device 2.

In the receiver 2B of the data reception-side communication device 2, the packet is received from the communication device 1 and the information bit sequence lying in the packet is demodulated by the demodulator 16. The demodulated information bit sequence is stored in the corresponding buffer in the buffer selector 17A from which it is supplied to the CRC circuit 20.

The CRC circuit 20 performs a CRC check for the demodulated information bit sequence (Step S22). The result of its CRC check is supplied to the transmitter 2A of the reception-side communication device 2.

When the above result of CRC check is found to be affirmative or acknowledged, the information bit sequence corresponding to the nth block is obtained as normal bit data. Therefore, the transmitter 2A sends a response packet indicative of ACK to the data transmission-side communication device 1 (Step S23). When the result of CRC result is found to be negative or negative-acknowledged, the information bit sequence corresponding to the nth block cannot be obtained as the normal bit data. Therefore, the transmitter 2A sends a response packet indicative of NACK to the communication device 1 (Step S24).

When the response packet indicative of NACK is received by the receiver 1B of the data transmission-side communication device 1, the transmitter 1A executes the modulation/transmission of only a first parity bit sequence (Step S25). That is, in the transmitter 1A, the buffer selector 13A selects a parity bit sequence outputted this time from the systematic encoder 12A and relay-supplies it to the modulator 14. Thus, a transmission packet corresponding to only the parity bit sequence is transmitted from the modulator 14 to the receiver 2B of the data reception-side communication device 2.

In the receiver 2B of the data reception-side communication device 2, the packet corresponding to only the parity bit sequence is received from the communication device 1 as a bit sequence. The parity bit sequence in the packet is demodulated by the demodulator 16. The demodulated parity bit sequence is stored in the corresponding buffer provided within the buffer selector 17A from which it is supplied to the error correction decoder 19. The information bit sequence already stored in the buffer lying in the buffer selector 17A is also supplied from the buffer selector 17A to the error correction decoder 19. The error correction decoder 19 performs error correction decoding on the information bit sequence using the parity bit sequence. The information bit sequence subsequent to the bit error correction is supplied to the CRC circuit 20.

The CRC circuit 20 performs a CRC check for the demodulated information bit sequence (Step S26). The result of its CRC check is supplied to the transmitter 2A of the reception-side communication device 2.

When the above result of CRC check is found to be affirmative or acknowledged, the transmitter 2A sends a response packet indicative of ACK to the data transmission-side communication device 1 (Step S27). When the result of CRC check is found to be deffirmative or negative-acknowledged, the transmitter 2A transmits a response packet indicative of NACK to the communication device 1 (Step S28).

When the response packet indicative of NACK is received by the receiver 1B of the data transmission-side communication device 1, the routine operation of the sequence diagram is returned to Step S1, where the transmitter 1A executes the modulation/transmission of only the information bit sequence corresponding to the nth block again.

When the response packet indicative of ACK is received by the receiver 1B of the data transmission-side communication device 1, the transmitter 1A selects an information bit sequence corresponding to an n+1th block outputted next from the systematic encoder 12A and relay-supplies it to the modulator 14. Thus, a transmission packet related to only the information bit sequence corresponding to the n+1th block is transmitted from the modulator 14 to the receiver 2B of the data reception-side communication device 2 (Step S29).

Thus, in the digital communication system according to another embodiment, it is shown that the present invention can be implemented even though a normal systematic code is adopted without using a turbo code. Since an interleaving memory is mounted on the transmission side in the turbo encoder and the turbo decoder also performs repetitive decoding, throughput is increased. According to the present embodiment, an information bit sequence can be transmitted at a bit rate corresponding to the transmission state of a transmission line by means of a small-scale circuit without estimating the transmission state of the transmission line, even in the case of such a device (e.g., IEEE802.11a/g) that the turbo encoder and turbo decoder large in load in this way cannot be mounted.

While the preferred forms of the present invention have been described, it is to be understood that modifications will be apparent to those skilled in the art without departing from the spirit of the invention. The scope of the invention is to be determined solely by the following claims.

1-8. (canceled)

9. A data transmission method comprising the following steps: on a transmitting side,
a first transmission step for adding a CRC (cyclic redundancy check) bit to an input information bit sequence in block units, modulating the information bit sequence subsequent to the addition of the CRC bit and transmitting the same to a receiving side; and
a second transmission step for, when a first NACK (negative-acknowledgement response) signal transmitted from the receiving side is received after execution of the first transmission step, systematically encoding the information bit sequence subsequent to the addition of the CRC bit thereby to generate a fist parity bit sequence, modulating the first parity bit sequence and transmitting the same to the receiving side; and comprising the following steps: on the receiving side,
a first check step for receiving the information bit sequence, demodulating the same and performing a CRC check for the post-demodulation information bit sequence;
a first NACK transmission step for transmitting the first NACK signal to the transmitting side when a result of said CRC check is found to be negative-acknowledged; and
a correction decoding step for receiving the first parity bit sequence, demodulating the same and performing error correction decoding on the post-demodulation information bit sequence using the demodulated first parity bit sequence.

10. The data transmission method according to claim 9, further including: on the transmitting side,
a third transmission step for, when a second NACK signal transmitted from the receiving side is received after execution of the second transmission step, turbo-encoding the information bit sequence subsequent to the addition of the CRC bit thereby to generate a second parity bit sequence, modulating the second parity bit sequence and transmitting the same to the receiving side; and including, on the receiving side,
a second check step for performing a CRC check for the information bit sequence subjected to the error correction decoding in the correction decoding step;
a second NACK transmission step for transmitting the second NACK signal to the transmitting side when a result of said CRC check in the second check step is found to be negative-acknowledged; and
a turbo decoding step for receiving the second parity bit sequence, demodulating the same and turbo-decoding the post-demodulation information bit sequence using the demodulated second parity bit sequence.

11. The data transmission method according to claim 9, further including: on the receiving side,
a third check step for performing a CRC check for the information bit sequence turbo-decoded in the turbo decoding step; and
a third NACK transmission step for transmitting a third NACK signal to the transmitting side when a result of said CRC check in the third check step is found to be negative-acknowledged, and,
wherein, on the transmitting side, when the third NACK signal transmitted from the receiving side is received after execution of the third transmission step, the first transmission step is performed on the same block as the input information bit sequence again.

12. The data transmission method according to claim 10, further including: on the receiving side,
a third check step for performing a CRC check for the information bit sequence turbo-decoded in the turbo decoding step; and
a third NACK transmission step for transmitting a third NACK signal to the transmitting side when a result of said CRC check in the third check step is found to be negative-acknowledged, and,
wherein, on the transmitting side, when the third NACK signal transmitted from the receiving side is received after execution of the third transmission step, the first transmission step is performed on the same block as the input information bit sequence again.

13. The data transmission method according to claim 9, further including, on the receiving side, an ACK transmission step for transmitting an ACK (acknowledgement response) signal to the transmitting side when the result of CRC check in any one of the first through third check steps is found to be acknowledged,
wherein, on the transmitting side, the first transmission step is performed on the following block of the input information bit sequence when the ACK signal transmitted from the receiving side is received.

14. The data transmission method according to claim 10, further including, on the receiving side, an ACK transmission step for transmitting an ACK (acknowledgement response) signal to the transmitting side when the result of CRC check in any one of the first through third check steps is found to be acknowledged,
wherein, on the transmitting side, the first transmission step is performed on the following block of the input information bit sequence when the ACK signal transmitted from the receiving side is received.

15. The data transmission method according to claim 11, further including, on the receiving side, an ACK transmission step for transmitting an ACK (acknowledgement response) signal to the transmitting side when the result of CRC check in any one of the first through third check steps is found to be acknowledged,
wherein, on the transmitting side, the first transmission step is performed on the following block of the input information bit sequence when the ACK signal transmitted from the receiving side is received.

16. The data transmission method according to claim 12, further including, on the receiving side, an ACK transmission step for transmitting an ACK (acknowledgement response) signal to the transmitting side when the result of CRC check in any one of the first through third check steps is found to be acknowledged,
wherein, on the transmitting side, the first transmission step is performed on the following block of the input information bit sequence when the ACK signal transmitted from the receiving side is received.

17. A transmitter comprising:
CRC adding means which adds a CRC bit to an input information bit sequence in block units;
encoding means which systematically encodes the information bit sequence subsequent to the addition of the CRC bit by the CRC adding means thereby to generate a first parity bit sequence;
selecting means which selectively outputs either one of the information bit sequence subsequent to the addition of the CRC bit and the first parity bit sequence; and
modulating means which modulates the first bit sequence outputted by the selecting means and transmits the same therefrom.

18. The transmitter according to claim 17, further including turbo encoding means which turbo-encodes the information bit sequence subsequent to the addition of the CRC bit thereby to generate a second parity bit sequence,
wherein the selecting means selectively outputs any one of the information bit sequence subsequent to the addition of the CRC bit, the first parity bit sequence and the second parity bit sequence.

19. A receiver comprising:
demodulating means which individually receives, in block units, an information bit sequence subsequent to addition of a CRC bit and a first parity bit sequence obtained by systematically encoding the information bit sequence subsequent to the addition of the CRC bit;
decoding means which performs error correction decoding on the information bit sequence demodulated by the demodulating means, using the first parity bit sequence demodulated by the demodulating means; and
check means which performs a CRC check for the information bit sequence demodulated by the demodulating means or the information bit sequence subjected to the error correction decoding by the decoding means.

20. The receiver according to claim 19, wherein the demodulating means individually receives, in block units, the information bit sequence subsequent to the addition of the CRC bit, the first parity bit sequence and the second parity bit sequence obtained by turbo-encoding the information bit sequence subsequent to the addition of the CRC bit and demodulates the same, and
wherein the decoding means has turbo decoding means which turbo-decodes the information bit sequence demodulated by the demodulating means, using the first and second parity sequences demodulated by the demodulating means.
